(19) United States
(12) Patent Application Publication
(10) Pub. No.: US 2024/0218508 A1
(43) Pub. Date: Jul. 4, 2024

(54) RUNOUT AND WOBBLE MEASUREMENT FIXTURES

(71) Applicant: ASM IP Holding B.V., Almere (NL)

(72) Inventors: Aniket Nitin Patil, Tempe, AZ (US); Saket Rathi, Santa Clara, CA (US); Sam Kim, Chandler, AZ (US); Shiva K.T. Rajavelu Muralidhar, San Diego, CA (US)

(21) Appl. No.: 18/609,379

(22) Filed: Mar. 19, 2024

Related U.S. Application Data
(62) Division of application No. 17/549,022, filed on Dec. 13, 2021, now Pat. No. 11,946,137.
(60) Provisional application No. 63/126,187, filed on Dec. 16, 2020.

(51) Int. Cl. C23C 16/455; B23Q 3/00; C23C 16/458; C23C 16/52

(52) U.S. Cl. CPC C23C 16/455; B23Q 3/00; C23C 16/4582; C23C 16/52

(57) ABSTRACT

A fixture is provided. The fixture includes a base, a turntable, a first sensor, and a second sensor. The turntable is supported on the base, is rotatable about a rotation axis, and is configured to slidably seat a susceptor assembly for rotation about the rotation axis. The first sensor is fixed relative to the base, is radially offset from the rotation axis, and is configured to determine ex-situ runout of the susceptor assembly. The second sensor is fixed relative to the first sensor, is axially offset from the first sensor, and is configured to determine ex-situ wobble of the susceptor assembly. Fixture arrangements and methods of determining ex-situ runout and ex-situ wobble of susceptor assemblies for semiconductor processing systems are also described.

### CROSS-REFERENCE TO RELATED APPLICATIONS

This application is a divisional of, and claims priority to and the benefit of, U.S. patent application Ser. No. 17/549,022, filed Dec. 13, 2021 and entitled “RUNOUT AND WOBBLE MEASUREMENT FIXTURES,” which is a non-provisional of, and claims priority to and the benefit of, U.S. Provisional Patent Application No. 63/126,187, filed Dec. 16, 2020 and entitled “RUNOUT AND WOBBLE MEASUREMENT FIXTURES,” which are hereby incorporated by reference herein.

### FIELD OF INVENTION

The present disclosure generally relates to semiconductor processing systems. More particularly, the present disclosure relates to making semiconductor processing systems, such as semiconductor processing systems for depositing films onto substrates.

### BACKGROUND OF THE DISCLOSURE

Semiconductor processing systems are commonly used to deposit films onto substrates, such as during the fabrication of very large-scale integrated circuits. Film deposition is generally accomplished is such semiconductor processing systems by supporting the substrate within a reaction chamber and flowing a precursor gas through the reaction chamber and across the substrate. The reaction chamber typically maintains the substrate in an environment conducive for deposition of a film onto the substrate while flowing the precursor gas across the substrate. The substrate is typically supported by a susceptor assembly, which seats the substrate on a shaft-driven susceptor, and which rotates within the reaction chamber as the precursor flows across the substrate to promote uniformity in the film deposited onto the substrate.

In some semiconductor processing devices, film uniformity may be influenced by runout and/or wobble of the susceptor assembly during rotation relative to the surrounding reaction chamber structure. For example, excessive amounts of runout, i.e., radial displacement of a point located at the periphery of the susceptor assembly during rotation relative to surrounding reaction chamber structure, may, in some semiconductor processing system, limit uniformity of a film deposited onto a substrate supported by a susceptor. Excessive amounts of wobble, i.e., axial displacement of a point located on the surface of the susceptor assembly during rotation relative to surrounding reaction chamber structure, may, in some semiconductor processing, also limit uniformity of a film deposited onto a substrate supported by the susceptor assembly.

Runout and wobble may be controlled through piece part-level manufacturing tolerances and in-situ adjustment of the susceptor assembly during system-level installation and qualification. Piece part-level manufacturing tolerances, for example, generally ensure that each component selected for a particular susceptor assembly conforms to certain predetermined manufacturing tolerances, thereby ensuring that no piece-part will individually impart excessive runout and/or wobble into the susceptor assembly once the susceptor assembled within the reaction chamber. In-situ qualification of the susceptor assembly once assembled within the reaction chamber typically allows runout and/or wobble of the susceptor assembly to be adjusted to within predetermined limits. Susceptor assembly adjustments are generally able to limit runout and/or wobble where the tolerance stack-up of the piece-parts permits successful adjustment of the assembled piece parts.

Such semiconductor processing systems and methods of making semiconductor processing systems have generally been suitable for their intended purpose. However, there remains a need in the art for improved fixtures, fixture arrangements, and methods of determining runout and wobble of susceptor assemblies for semiconductor processing systems. The present disclosure provides a solution to this need.

### SUMMARY OF THE DISCLOSURE

A fixture is provided. The fixture includes a base, a turntable, a first sensor, and a second sensor. The turntable is supported on the base, is rotatable about a rotation axis, and is configured to slidably seat a susceptor assembly for rotation about the rotation axis. The first sensor is fixed relative to the base, is radially offset from the rotation axis, and is configured to determine ex-situ runout of the susceptor assembly. The second sensor is fixed relative to the first sensor, is axially offset from the first sensor, and is configured to determine ex-situ wobble of the susceptor assembly.

In certain examples, the first sensor may be a first non-contact sensor and the second sensor may be a second non-contact sensor.

In certain examples, the first sensor may include a first laser displacement sensor and the second sensor may include a second laser displacement sensor.

In certain examples, at least one of the first laser displacement sensor and the second laser displacement sensor may have a spot size between about 120 microns and about 1300 microns.

In certain examples, at least one of the first laser displacement sensor and the second laser displacement sensor may include (a) a visible illumination source, (b) a red illumination source, or (c) a 655-nanometer illumination source.

In certain examples, the fixture may include at least one handle extending laterally from the base and radially offset from the rotation axis.

In certain examples, the fixture may include a pedestal fixed to the base and radially offset from the rotation axis. One or more of the first sensor and the second sensor may be fixed to the pedestal.

In certain examples, the fixture may include a bracket fixing at least one of the first sensor and the second sensor to the pedestal. The bracket may define (a) a runout surface that is substantially orthogonal to the rotation axis or (b) a wobble surface that is substantially parallel to the rotation axis.

In certain examples, the pedestal may be a first pedestal fixing the first sensor to the base and the fixture may include a first bracket, a second pedestal, and a second bracket. The first bracket may fix the first sensor to the first pedestal, may define a define a runout surface that is substantially orthogonal relative to the rotation axis, and may support thereon the first sensor. The second pedestal may be fixed to the base, may be circumferentially offset from the first sensor about the rotation axis, and may fix the second sensor to the base. The second bracket may fix the second sensor to the second pedestal, may define a wobble surface that is substantially parallel to the rotation axis, and may support the second sensor on the wobble surface.

In certain examples, the turntable may include a lower member, an intermediate member, and an upper member. The lower member may be fixed to the base and have a bearing arrangement. The intermediate member may be rotatably supported on the lower member by the bearing arrangement and may have a stop portion arranged along the rotation axis. The upper member may be fixed to the intermediate member and may have a sleeve portion that extends about the rotation axis and axially from the shaft stop.

In certain examples, the turntable may include a first resilient member and a second resilient member. The first resilient member may be seated in the sleeve portion of the upper member, may extend about the rotation axis, and may be axially offset from the lower member. The second resilient member maybe seated in the sleeve portion, may extend about the rotation axis, may be axially offset from the first resilient member, and may be arranged along the rotation axis on a side of the first resilient member opposite the lower member.

In certain examples, the intermediate member may be (a) captive within the upper member of the turntable, or (b) captive between the lower member and the upper member of the turntable.

In certain examples, a susceptor assembly may be slidably received in the turntable and rotatable therein about the rotation axis relative to the base.

In certain examples, the susceptor assembly may include a spider. The spider may be arranged along the rotation axis. The spider may be located axially between the second sensor and the turntable.

In certain examples, the susceptor assembly may include a susceptor. The susceptor may be arranged along the rotation axis. The susceptor may be axially offset from the turntable. The susceptor may be radially overlapped by the first sensor. The susceptor may be axially overlapped by the second sensor.

In certain examples, the susceptor assembly may include a shaft with a lower end and an upper end. The lower end of the shaft may be slidably received in the turntable. The upper end of the shaft may be arranged between the second sensor and the turntable.

In certain examples, the fixture may include a controller. The controller may be disposed in communication with the first sensor and the second sensor. The controller may be disposed in communication with a non-transitory machine-readable memory. The controller may be responsive to instructions recorded on the memory to receive a plurality of radial displacement measurements of the susceptor assembly from the first sensor, receive a plurality of axial displacement measurements of the susceptor assembly from the second sensor, determine ex-situ runout of the susceptor assembly using the plurality of radial displacements received from the first sensor, and determine ex-situ wobble of the susceptor assembly using the plurality of axial displacement measurements received from the second sensor.

A fixture arrangement is provided. The fixture arrangement includes a fixture as described above and a susceptor assembly. The first sensor is a first non-contact sensor, the second sensor is a second non-contact senor, the first sensor includes a first laser displacement sensor, and the second sensor includes a second laser displacement sensor. The susceptor assembly is slidably seated in the turntable, is rotatable therein about the rotation axis relative to the base, and includes a shaft, a spider, and a susceptor. The shaft has a lower end that is slidably received in the turntable and an upper end arranged between the second sensor and the turntable. The spider is arranged along the rotation axis, is located axially between the second sensor and the turntable and is fixed to the upper end of the shaft. The susceptor is arranged along the rotation axis, is axially offset from the turntable, is fixed to the upper end of the shaft by the spider, is radially overlapped by the first sensor, and is axially overlapped by the second sensor.

A method of determining ex-situ runout and ex-situ wobble of a susceptor assembly for a semiconductor processing system is provided. The method includes, at a fixture as described above, slidably seating a susceptor assembly in the turntable for rotation about the rotation axis, determining ex-situ runout of the susceptor assembly using the first sensor, and determining ex-situ wobble of the susceptor assembly using the second sensor. The ex-situ runout is compared to a predetermined ex-situ runout value and the susceptor assembly reworked when the ex-situ runout exceeds the predetermined ex-situ runout value, the ex-situ wobble is compared to a predetermined ex-situ wobble value and the susceptor assembly reworked when the ex-situ wobble value exceeds the predetermined ex-situ wobble value, and the susceptor assembly disassembled when (a) the ex-situ runout is below the predetermined ex-situ runout value and (b) the ex-situ wobble is below the predetermined ex-situ wobble value.

In certain examples, the method may include reassembling the susceptor assembly within a semiconductor processing device, determining in-situ runout of the susceptor assembly, and determining in-situ wobble of the susceptor assembly. The in-situ runout may be compared to the predetermined in-situ runout value and the susceptor assembly reworked when the in-situ runout exceeds the predetermined in-situ runout value, the in-situ wobble may be compared to the predetermined in-situ wobble value and susceptor assembly reworked when the in-situ wobble value exceeds the predetermined in-situ wobble value.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a fixture constructed in accordance with the present disclosure, showing a susceptor assembly rotatably seated in a turntable with a first sensor and a second sensor for determining in-situ runout and in-situ wobble of the susceptor assembly;

FIG. 2 is a schematic view of the fixture of FIG. 1, showing first and second sensor fixed relative to a frame and determining in-situ runout and wobble of the susceptor assembly using radial and axial displacement measurements of the susceptor assembly;

FIG. 3 is a schematic view of the fixture of FIG. 1 according to an example, showing a first pedestal supporting the first sensor and a second pedestal supporting the second for determining ex-situ runout and ex-situ wobble using the first sensor and the second sensor;

FIG. 4 is a schematic view of the fixture of FIG. 1 according to another example, showing a controller disposed in communication with the first sensor and the second sensor to calculate ex-situ runout and ex-situ wobble of the susceptor assembly using radial and axial measurements received from the first sensor and the second sensor, respectively;

FIG. 5 is a cross-sectional side view of the turntable of the fixture of FIG. 1 according to an example, showing an intermediate member with a stop portion captive within an upper member and along the rotation axis;

FIG. 6 is a cross-sectional side view of the turntable of the fixture of FIG. 1 according to another example, showing an intermediate member with a stop portion captive between an upper member and a lower member of the turntable and along the rotation axis;

FIG. 7 is a block diagram of a method of determining ex-situ runout and ex-situ wobble of a susceptor assembly in accordance with the present disclosure, showing operations of the method according to an illustrative and non-limiting example of the method; and

FIG. 8 is a block diagram of a method of determining in-situ runout and in-situ wobble of a susceptor assembly in accordance with the present disclosure, showing operations of the method according to another illustrative and non-limiting example of the method.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

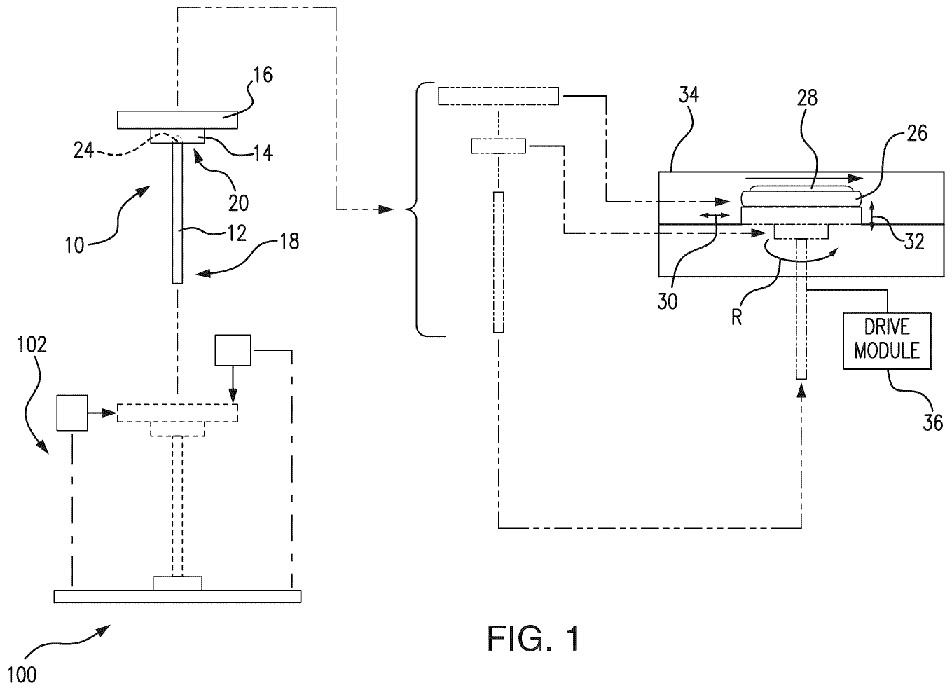

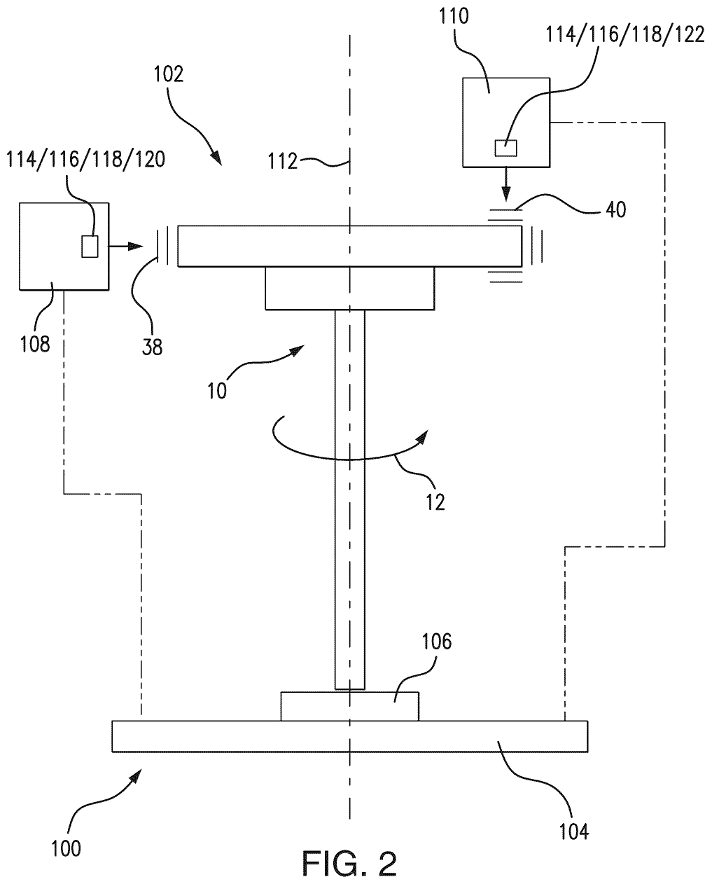

Reference will now be made to the drawings wherein like reference numerals identify similar structural features or aspects of the subject disclosure. For purposes of explanation and illustration, and not limitation, a partial view of an example of a fixture in accordance with the disclosure is shown in FIG. 1 and is designated generally by reference character 100. Other embodiments of fixtures, fixture arrangements, and methods of determining runout and wobble of susceptor assemblies for semiconductor processing systems in accordance with the present disclosure, or aspects thereof, are provided in FIGS. 2-8, as will be described. The fixtures, fixture arrangements, and methods of determining ex-situ runout and ex-situ wobble in susceptor assemblies for assemblies can be used for making susceptor assemblies for semiconductor processing systems, such as atmospheric chemical vapor deposition (CVD) systems used to deposit films using epitaxial techniques, though the present disclosure is not limited to epitaxial techniques or to CVD semiconductor processing systems in general.

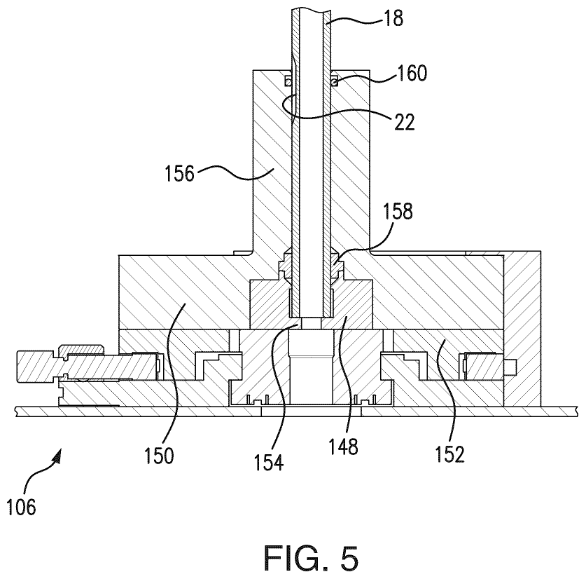

Referring to FIG. 1, a fixture arrangement 102 including the fixture 100 and a susceptor assembly 10 is shown. The susceptor assembly 10 includes a shaft 12, a spider 14, and a susceptor 16. The shaft 12 has a lower end 18 and a longitudinally opposite upper end 20. The lower end 18 of the shaft 12 is slidably received within the fixture 100 and may have a locking groove 22 (shown in FIG. 5). The upper end 20 of the shaft 12 has a spider seat 24 and fixedly seats thereon the spider 14. The spider 14 is fixed in rotation relative to the shaft 12 and in turn seats the susceptor 16. The susceptor 16 is in turn fixed in rotation relative to the spider 14 and is configured to support a substrate 26 during deposition of a film 28 onto the substrate 26. It is contemplated that susceptor assembly 10 may be as shown and described in U.S. Pat. No. 6,086,680 issued on Jul. 11, 2000, the contents of which are incorporated herein by reference in its entirety.

As has been explained above, in some semiconductor processing systems, it can be desirable to limit in-situ runout and in-situ wobble of a susceptor assembly during the deposition of a film onto the substrate supported by a susceptor assembly, e.g., the in-situ runout 30 and/or the in-situ wobble 32 during deposition of the film 28 onto the substrate 26 while supported by the susceptor assembly 10. Limiting in-situ runout and in-situ wobble is generally accomplished by adjusting and/or replacing parts of the susceptor assembly, e.g., by adjusting seating of the spider 14 on the spider seat 24 and/or seating of the susceptor 16 on the spider 14, typically delaying qualification of the semiconductor processing system into which the susceptor assembly has been installed. As used herein the term “runout” refers to radial movement of a point located on a radially outer periphery of the susceptor assembly 10 during rotation about a rotation axis and relative to the rotation axis. As used herein the term “wobble” refers to axial displacement of a point located on the susceptor assembly 10 during rotation about the rotation axis and relative to the rotation axis.

Without being bound by a theory, applicant believes that the difficulty in making adjustments to a given susceptor assembly in-situ corresponds to manufacturing variation within the various piece parts selected for the susceptor assembly. Specifically, while each of the selected piece parts may individually conform to the tolerances governing each piece part type, the tolerance stack-up of the piece arts within a specific susceptor assembly may sometimes result in the susceptor assembly exhibiting in-situ runout and/or in-situ wobble that exceeds a predetermined in-situ runout value and/or a predetermined in-situ wobble value. And while the in-situ runout and the in-situ wobble of the susceptor assembly may generally successfully adjusted subsequent to assembly of the susceptor assembly within a semiconductor processing system, the need for such adjustments prolongs the installation and/or qualification of the semiconductor processing system into which the susceptor assembly has been assembled. Therefore, to simplify qualification of the semiconductor processing system, the fixture 100 is provided.

With reference to FIG. 2, a fixture arrangement 102 including the fixture 100 and a susceptor assembly 10 is shown. The fixture 100 includes a base 104, a turntable 106, a first sensor 108, and a second sensor 110. The turntable 106 is supported on the base 104, is rotatable about a rotation axis 112, and is configured to slidably seat therein the susceptor assembly 10 for rotation R relative to the base 104 about the rotation axis 112. The first sensor 108 is fixed relative to the base 104, is radially offset from the rotation axis 112, and is configured to determine ex-situ runout 38 of the susceptor assembly 10. The second sensor 110 is fixed relative to the base 104, is axially offset from the first sensor 108 along the rotation axis 112 and is configured to determine ex-situ wobble 40 of the susceptor assembly 10.

One or more of the first sensor 108 and the second sensor 110 may be a non-contact sensor, e.g., an optical sensor. As will be appreciated by those of skill in the art in view of the present disclosure, employment of non-contact sensors limits (or eliminates) contamination of the susceptor assembly 10 that may otherwise result from contact of a gauge or measurement instrument with the susceptor assembly 10. As will also be appreciated by those of skill in the art in view of the present disclosure, non-contact sensors also limit (or eliminate) risk of contaminating the susceptor assembly 10 with particles, such as metallic particles, during the determination of the ex-situ runout 38 and the ex-situ wobble 40 of the susceptor assembly 10, limiting (or eliminating) the need to clean the susceptor assembly 10 subsequent to determining the ex-situ runout 38 and the ex-situ wobble 40 of the susceptor assembly 10.

One or more of the first sensor 108 and the second sensor 110 may include a (a) a visible illumination source 114, (b) a red illumination source 116, or (c) a 655-nanometer illumination source 118. Employment of such illumination sources simplifies determining the ex-situ runout 38 and the ex-situ wobble 40 by allowing a user to visually confirm that both the first sensor 108 and the second sensor 110 remain optically coupled with the susceptor assembly 10 during rotation about the rotation axis 112, simplifying techniques requirement measurement of spot size on the surface of the susceptor assembly 10. Such illumination sources may also be eye-safe, limiting risk of injury to the user during the determination of the ex-situ runout 38 and the wobble 32 of the susceptor assembly 10.

One or more of the first sensor 108 and the second sensor 110 may include a laser displacement sensor, e.g., a first laser displacement sensor 120 and/or a second laser displacement sensor 122 (shown in FIG. 2). In certain examples either (or both) the first laser displacement sensor 120 and/or the second laser displacement sensor 122 may have a spot size that is about 1200 microns in width, allowing determination of the runout 30 and/or wobble 32 without a computer, simplifying employment of the fixture 100. Examples of such laser displacement sensors include IL-152 sensors, available from the Keyence Corporation of Itasca, Illinois.

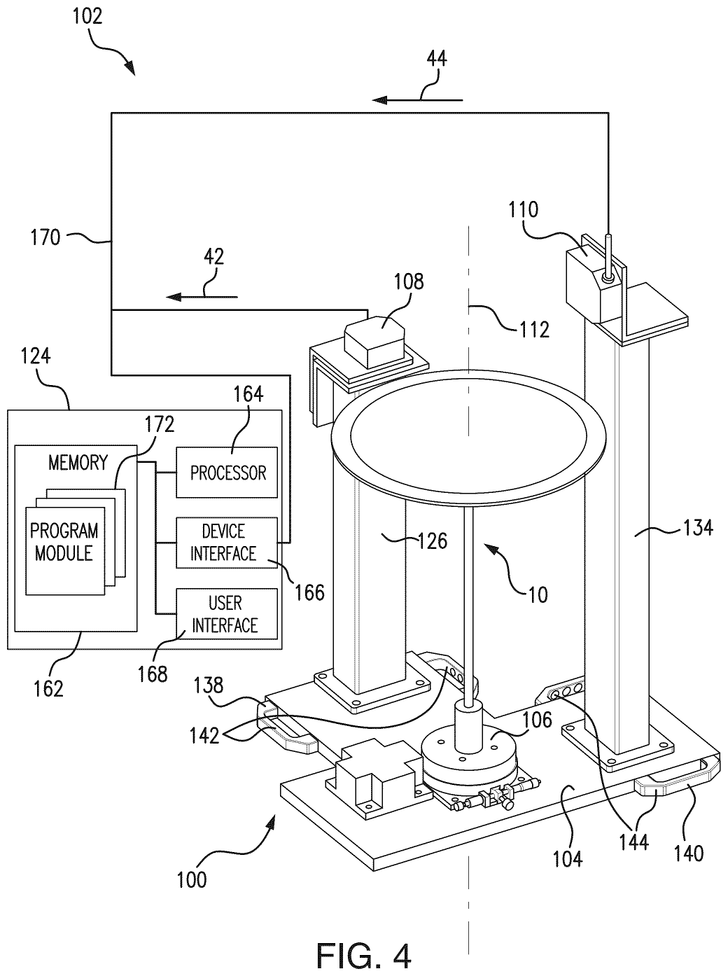

In accordance with certain examples, either (or both) the first laser displacement sensor 120 and/or the second laser displacement sensor 122 may have a spot size of about 120 microns. In such examples the first laser displacement sensor 120 and/or the second laser displacement sensor 122 may determine the ex-situ runout 38 and ex-situ wobble 40 of the susceptor assembly 10 in cooperation with a controller, e.g., a controller 124 (shown in FIG. 4), allowing for automation of the determination of the ex-situ runout 38 and ex-situ wobble 40 of the susceptor assembly 10. Examples of such laser displacement sensors include HK-152 sensors, also available from the Keyence Corporation of Itasca, Illinois.

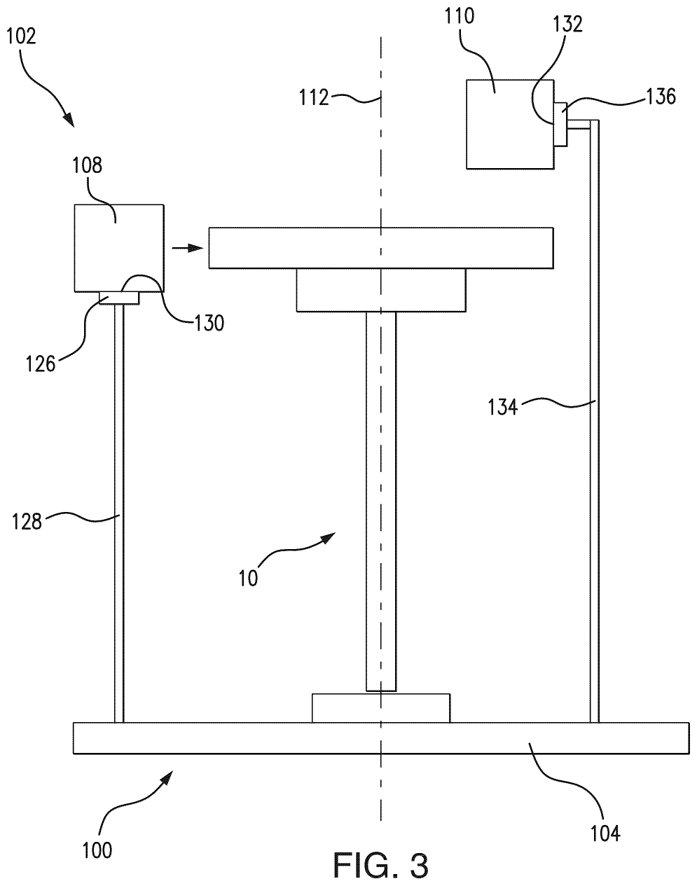

With reference to FIG. 3, the fixture 100 is shown according to an example include a pedestal 126 and a bracket 128. The pedestal 126 is fixed to the base 104, is radially offset from the rotation axis 112, and at least one of the first sensor 108 and the second sensor 110 is supported by the pedestal 126. It is contemplated that the bracket 128 fix at least one of the first sensor 108 and the second sensor 110 to the pedestal 126. It is contemplated that the bracket 128 define a runout surface 130 or a wobble surface 132, the runout surface 130 being substantially orthogonal relative to the rotation axis 112 and the wobble surface 132 being substantially parallel relative to the rotation axis 112. As will be appreciated by those of skill in the art in view of the present disclosure, employment of the bracket 128 may simplify the setup and/or maintenance of the fixture 100, e.g., by allowing qualification and/or certification of the fixture 100 through adjustment of the runout surface 130 or the wobble surface 132.

In the illustrated example the pedestal 126 is a first pedestal 126, the bracket 128 is a first bracket 128, and the fixture 100 further includes a second pedestal 134 and a second bracket 136. The first pedestal 126 is connected to the base 104, extends axially along the rotation axis 112, and supports the first sensor 108. In this respect the first bracket 128 is connected the first pedestal 126, is connected through the first pedestal 126 to the base 104 and defines the runout surface 130. The runout surface 130 is planar, is orthogonal relative to the rotation axis 112, and supports thereon the first sensor 108. It is contemplated that the first sensor 108 be supported on the runout surface 130 such that the susceptor assembly 10 is in direct line of sight with the first sensor 108, e.g., without an intervening structure between the first sensor 108 and the susceptor assembly 10. As will be appreciated by those of skill in the art in view of the present disclosure, the direct line of sight limits the output power requirement of the first sensor 108, simplifying determination of the ex-situ runout 38 (shown in FIG. 1) of the susceptor assembly 10.

The second pedestal 134 is similar to the first pedestal 126, is additionally offset from the first pedestal 126 about the rotation axis 112 and further has an axial height that is greater than an axial height of the first pedestal 126. In this respect the second pedestal 134 is connected to the base 104, extends axially along the rotation axis 112, and supports the second sensor 110. The second bracket 136 is connected to the second pedestal 134, is connected through the second pedestal 134 to the base 104 and defines the wobble surface 132. The wobble surface 132 is planar, extends in parallel relative to the rotation axis 112, and supports thereon the second sensor 110. It is contemplated that the second sensor 110 be supported on the wobble surface 132 such that the susceptor assembly 10 is in direct line of sight with the second sensor 110, e.g., also without any intervening structure between the second sensor 110 and the susceptor assembly 10. As will be also appreciated by those of skill in the art in view of the present disclosure, the direct line of sight limits the output power requirement of the second sensor 110, simplifying determination of the wobble 32 (shown in FIG. 1) of the susceptor assembly 10.

With reference to FIG. 4, the fixture 100 is shown according an example having the controller 124, a first handle 138, and a second handle 140. The first handle 138 extends laterally from the base 104 and at a location radially offset from the rotation axis 112 and adjacent to the first pedestal 126. The second handle 140 is similar to the first handle 138, is additionally offset from the first handle 138 about the rotation axis 112, and further extends laterally from the base 104 at a location radially offset from the rotation axis 112 and adjacent to the second pedestal 134. Locating the first handle 138 adjacent to the first pedestal 126 and the second handle 140 adjacent to the second pedestal 134 simplifies handling of the fixture 100 as both the first handle 138 and the second handle 140 are proximate the center of gravity of the fixture 100.

It is contemplated that the first handle 138 may be one of a first handle pair 142, the first handle pair 142 distributed on opposite sides the first pedestal 126 and radially offset from the rotation axis 112. It is also contemplated that the second handle 140 may be one of a second handle pair 144, the second handle pair 144 distributed on opposite sides of the second pedestal 134 and radially offset from the rotation axis 112. As will be appreciated by those of skill in the art in view of the present disclosure, the first handle 138, the second handle 140, the first handle pair 142, and/or the second handle pair 144 allow the base 104 to be relative thick, which can limit the impact that vibration in the ambient environment may have on determining the ex-situ runout 38 and the ex-situ wobble 40 of the susceptor assembly 10 using the fixture 100. The first handle pair 142 and the second handle pair 144 also allow for lifting the fixture 100 from location proximate the turntable 106, which may require more than one individual to lift and/or shift the fixture 100.

With reference to FIG. 5, the turntable 106 is shown. The turntable 106 includes a lower member 146, an intermediate member 148, and an upper member 150. The lower member 146 includes a bearing arrangement 152 and is fixed relative to the base 104. The intermediate member 148 is rotatably supported on the lower member 146 by the bearing arrangement 152 and has a stop portion 154, which is arranged along the rotation axis 112 and is configured to receive thereon the lower end 18 of the shaft 12 (shown in FIG. 1). The upper member 150 is fixed in rotation relative to the intermediate member 148, such as by one or more fastener, and has a sleeve portion 156. The sleeve portion 156 in turn extends about the rotation axis 112 and extends axially along the rotation axis 112 from the stop portion 154 of the intermediate member 148. In certain examples the turntable may have a crank for rotating the susceptor assembly 10 about the rotation axis 112.

The turntable 106 also includes a first resilient member 158 and a second resilient member 160. The first resilient member 158 is seated in the sleeve portion 156 of the upper member 150 and extends about the rotation axis 112. The first resilient member 158 is further axially offset from the stop portion 154 of the intermediate member 148. In certain examples, the first resilient member 158 may be an O-ring. In accordance with certain examples, the first resilient member 158 may be formed from an elastomeric material, such as rubber by way of non-limiting example.

The second resilient member 160 is seated in the sleeve portion 156 of the upper member 150 and extends about the rotation axis 112. The second resilient member 160 is further axially separated from the stop portion 154 of the intermediate member 148 by the first resilient member 158, and radially engages the locking groove 22 defined in the lower end 18 of the shaft 12 (shown in FIG. 1) such that the susceptor assembly 10 is fixed in rotation relative to the upper member 150 of the turntable 106 for coincident rotation therewith about the rotation axis 112. In certain examples, the second resilient member 160 may be an O-ring. In accordance with certain examples, the second resilient member 160 may be formed from an elastomeric material, such as rubber by way of non-limiting example. It is also contemplated that, in accordance with certain examples, that the second resilient member 160 may be substantially identical with the first resilient member 158 prior to assembly in the turntable 106.

As shown in FIG. 5, the intermediate member 148 may be captive within the upper member 150 of the turntable 106. Captive arrangement of the intermediate member 148 allows the upper member 150 to seat directly against the bearing arrangement 152, limiting the number of mechanical interfaces between the susceptor 16 (shown in FIG. 1) and limiting backlash in arrangements where a drive module, e.g., a drive module 36, is operatively associate with the susceptor assembly 10.

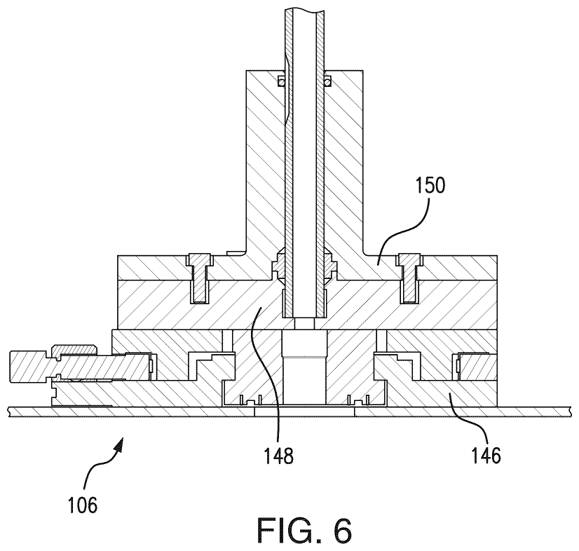

With reference to FIG. 6, the turntable 106 is shown according to another example wherein the intermediate member 148 is captive between the upper member 150 and the lower member 146. In such examples the turntable 106 may be easier to fabricate, which can reduce cost in testing environments applications where higher levels of backlash are acceptable.

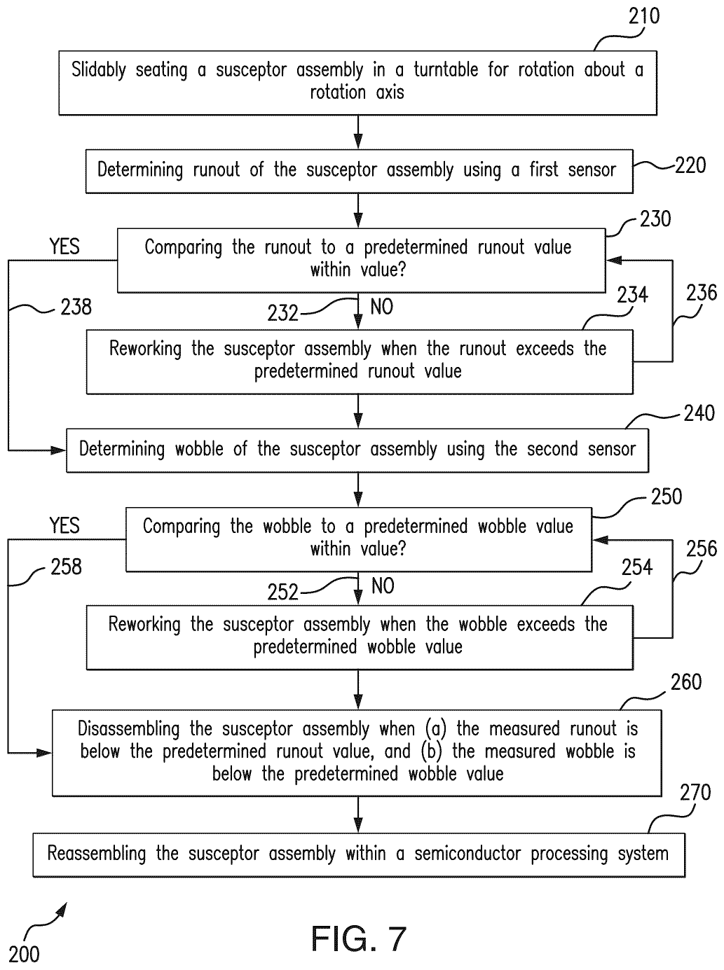

With continuing reference to FIG. 4, the controller 124 includes a memory 162, a processor 164, a device interface 166, and a user interface 168. The device interface 166 operably connects the processor 164 to the first sensor 108 and the second sensor 110, e.g., through a wired or wireless link 170. The processor 164 is disposed in communication with the memory 162 and is operably connected to the user interface 168 to communicate the ex-situ runout 38 (shown in FIG. 2) and/or the ex-situ wobble 40 (shown in FIG. 2) of the susceptor assembly 10 to a user. In certain examples, the memory 162 includes a non-transitory machine-readable medium having a plurality of program modules 172 recorded thereon containing instruction that, when read by the controller 124 cause the processer 164 to execute certain operations. Among those operations are operations of a method 200 (shown in FIG. 7) of determining runout and wobble of a susceptor assembly.

In certain examples, the instructions recorded in the plurality of program modules 172 may cause the processor 164 to (a) receive a plurality of radial displacement measurements 42 of the susceptor assembly 10 from the first sensor 108, and (b) receive a plurality of axial displacement measurements 44 of the susceptor assembly 10 from the second sensor 110. The instructions may further cause the controller 124 to (c) determine the ex-situ runout 38 (shown in FIG. 2) of the susceptor assembly 10 using the plurality of radial displacement measurements 42 received from the first sensor 108, and (d) determine the ex-situ wobble 40 of the susceptor assembly 10 using the plurality of axial displacement measurements 44 received from the second sensor 110. In certain examples, the controller 124 may include a stand-alone computer or a handheld device including the memory 162, as suitable for an intended application.

With reference to FIG. 7, the method 200 of determining ex-situ runout and ex-situ wobble of a susceptor assembly, e.g., the ex-situ runout 38 (shown in FIG. 2) and the ex-situ wobble 40 (shown in FIG. 2) of the susceptor assembly 10 (shown in FIG. 1), is shown. The method 200 generally includes determining ex-situ runout and ex-situ wobble of the susceptor assembly outside of a semiconductor processing system, e.g., the semiconductor processing system 34 (shown in FIG. 1). As shown with box 210, the susceptor assembly is slidably seated in a turntable for rotation about a rotation axis, e.g., the turntable 106 (shown in FIG. 2) for rotation about the rotation axis 112 (shown in FIG. 2). As shown with box 220, ex-situ runout of the susceptor assembly is determined while slidably seated in the turntable of the fixture for rotation about the rotation axis. As shown with box 240, ex-situ wobble of the susceptor assembly is determined while slidably seated in the turntable for rotation action about the rotation axis. In certain examples, ex-situ runout and ex-situ wobble may be determined coincident with one another, i.e. at the same time. As will be appreciated by those of skill in the art in view of the present disclosure, coincident determination of ex-situ runout and ex-situ wobble limits noise otherwise associated by acquiring the radial and axial displacement required for determining ex-situ runout and ex-situ wobble.

As shown with box 230, the ex-situ runout of the susceptor assembly is compared to a predetermined ex-situ runout value. When the ex-situ runout is above the predetermined ex-situ runout value the susceptor assembly is reworked and rechecked, as shown with arrow 232, box 234, and arrow 236. When the ex-situ runout is below the predetermined ex-situ runout value the ex-situ wobble of the susceptor assembly is determined, as shown with arrow 238. In certain examples, the ex-situ runout may be determined using a first sensor, e.g., the first sensor 108 (shown in FIG. 2). In accordance with certain examples, the ex-situ runout may be determined by calculating the ex-situ runout using a plurality of radial displacement measurements acquired from the susceptor assembly during rotation about the rotation axis, e.g., the radial displacement measurements 42 (shown in FIG. 4). It is contemplated that reworking the susceptor assembly may include adjusting seating of elements within the susceptor assembly. It is also contemplated that reworking the susceptor assembly may include altering contour of one or more seating surfaces within the susceptor assembly.

As shown with box 250, the ex-situ wobble of the susceptor assembly is compared to a predetermined ex-situ wobble value. When the ex-situ wobble is above the predetermined ex-situ wobble value the susceptor assembly is reworked and rechecked, as shown with arrow 252, box 254, and arrow 256. When (a) the ex-situ runout is below the predetermined ex-situ runout value and (b) the ex-situ wobble is below the predetermined ex-situ wobble value, the susceptor assembly is removed from the fixture and disassembled for reassembly within a susceptor assembly, as shown with arrow 258, box 260, and box 270.

In certain examples, the ex-situ wobble may be determined using a second sensor, e.g., the second sensor 110 (shown in FIG. 2). In accordance with certain examples, the ex-situ wobble may be determined by calculating the ex-situ wobble using a plurality of axial displacement measurements acquired during rotation of the susceptor assembly about the rotation axis, e.g., the axial displacement measurements 44 (shown in FIG. 4). It is contemplated that reworking the susceptor assembly may include adjusting seating of elements within the susceptor assembly. It is also contemplated that reworking the susceptor assembly may include altering contour of one or more seating surfaces within the susceptor assembly.

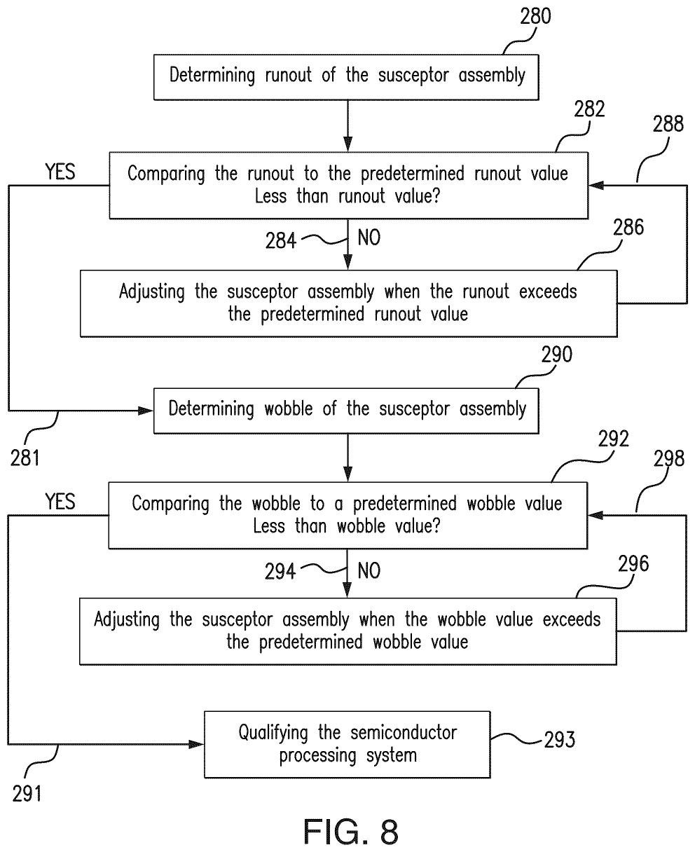

With reference to FIG. 8, the method 200 may also include determining in-situ runout and in-situ wobble, i.e., subsequent to reassembly of the susceptor within the semiconductor processing system, as shown with box 280. The method may further include determining in-situ wobble of the susceptor assembly, i.e., subsequent to reassembly of the susceptor assembly within the semiconductor processing system, as shown with box 290.

As shown with box 282, in-situ runout of the susceptor assembly, e.g., the in-situ runout 30 (shown in FIG. 1), is compared to a predetermined in-situ runout value. When the in-situ runout value is above the predetermined in-situ runout value the susceptor assembly is adjusted and rechecked, as shown with arrow 284, box 286, and arrow 288. When the in-situ runout is below the predetermined in-situ runout value, in-situ wobble of the susceptor assembly is determined, as shown with box 290. In certain examples, the predetermined ex-situ runout value may be equivalent to the predetermined in-situ runout value.

As shown with box 292, in-situ wobble of the susceptor assembly, e.g., the in-situ wobble 32 (shown in FIG. 1), is compared to a predetermined in-situ wobble value. When the in-situ wobble value is above the predetermined in-situ wobble value the susceptor assembly is adjusted and rechecked, as shown with arrow 294, box 296, and arrow 298. When the in-situ wobble is below the predetermined in-situ wobble value the semiconductor processing system is qualified for production, as shown with arrow 291 and box 293. Notably, as the susceptor assembly may be reworked to attend to excessive ex-situ runout and/or ex-situ wobble found while seated in the fixture, e.g., by adjusting contour of the spider seat 24 (shown in FIG. 1), the likelihood that adjustment will be required for excessive in-situ runout and/or in-situ wobble is reduced. In certain examples, the predetermined ex-situ wobble value may be equivalent to the predetermined in-situ wobble value.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

### ELEMENT LIST

10 Susceptor Assembly
12 Shaft
14 Spider
16 Susceptor
18 Lower End (of Shaft)
20 Upper End (of Shaft)
22 Locking Groove
24 Spider Seat
26 Substrate
28 Film
30 In-Situ Runout
32 In-Situ Wobble
34 Semiconductor Processing System
36 Drive Module
38 Ex-Situ Runout
40 Ex-Situ Runout
42 Radial Displacement Measurements
44 Axial Displacement Measurements
100 Fixture
102 Fixture Arrangement
104 Base
106 Turntable
108 First Sensor
110 Second Sensor
112 Rotation Axis
114 Visible Illumination Source
116 Red Illumination Source
118 655-Nanometer Illumination Source
120 First Laser Displacement Sensor
122 Second Laser Displacement Sensor
124 Controller
126 First Pedestal
128 First Bracket
130 Runout Surface
132 Wobble Surface
134 Second Pedestal
136 Second Bracket
138 First Handle
140 Second Handle
142 First Handle Pair
144 Second Handle Pair
146 Lower Member
148 Intermediate Member
150 Upper Member
152 Bearing Arrangement
154 Stop Portion
156 Sleeve Portion
158 First Resilient Member
160 Second Resilient Member
162 Memory
164 Processor
166 Device Interface
168 User Interface
170 Link
172 Program Modules
200 Method
210 Box
220 Box
230 Box
232 Arrow
234 Box
236 Arrow
238 Arrow
240 Box
250 Box
252 Arrow
254 Box
256 Arrow
258 Arrow
260 Box
270 Box
280 Box
282 Box
284 Arrow
286 Box
288 Arrow
281 Arrow
290 Box
292 Box
294 Arrow
296 Box
298 Arrow
291 Arrow
293 Box

1. A method of determining ex-situ runout and ex-situ wobble of a susceptor assembly, comprising:
at a fixture including a base, a turntable supported on the base and rotatable about a rotation axis, a first sensor fixed relative to the base and radially offset from the rotation axis, and a second sensor fixed relative to the first sensor and axially offset from the first sensor,
slidably seating a susceptor assembly in the turntable for rotation about the rotation axis;
determining ex-situ runout of the susceptor assembly using the first sensor;
determining ex-situ wobble of the susceptor assembly using the second sensor;
comparing the ex-situ runout to a predetermined ex-situ runout value and reworking the susceptor assembly when the ex-situ runout exceeds the predetermined ex-situ runout value;
comparing the ex-situ wobble to a predetermined ex-situ wobble value and reworking the susceptor assembly when the ex-situ wobble exceeds the predetermined ex-situ wobble value; and
disassembling the susceptor assembly when (a) the ex-situ runout is below the predetermined ex-situ runout value, and (b) the ex-situ wobble is below the predetermined ex-situ wobble value.

2. The method of claim 1, further comprising:
reassembling the susceptor assembly within a semiconductor processing device; and
determining in-situ runout of the susceptor assembly;
determining in-situ wobble of the susceptor assembly;
comparing the in-situ runout to a predetermined in-situ runout value and adjusting the susceptor assembly when the in-situ runout exceeds the predetermined in-situ runout value; and
comparing the in-situ wobble to a predetermined in-situ wobble value and adjusting the susceptor assembly when the in-situ wobble exceeds the predetermined in-situ wobble value.

3. The method of claim 1, further comprising:
receiving a plurality of radial displacement measurements from the first sensor, wherein the determining ex-situ runout of the susceptor assembly is completed using the plurality of radial displacement measurements.

4. The method of claim 3, further comprising:
acquiring the plurality of radial displacement measurements via the first sensor, prior to the receiving the plurality of radial displacement measurements, wherein the first sensor is a non-contact sensor.

5. The method of claim 1, further comprising:
receiving a plurality of axial displacement measurements from the second sensor, wherein the determining ex-situ wobble of the susceptor assembly is completed using the plurality of axial displacement measurements.

6. The method of claim 5, further comprising:
acquiring the plurality of axial displacement measurements via the second sensor, prior to the receiving the plurality of axial displacement measurements, wherein the second sensor is a non-contact sensor.

7. A method, comprising:
slidably seating a susceptor assembly in a turntable for rotation about a rotation axis;
determining runout of the susceptor assembly using a first sensor, wherein the first sensor is fixed relative to the turntable and radially offset from the rotation axis;
comparing the runout to a predetermined runout value and reworking the susceptor assembly in response to the runout exceeding the predetermined runout value; and
disassembling the susceptor assembly in response to the runout being below the predetermined runout value.

8. The method of claim 7, wherein the runout of the susceptor assembly that is determined and compared is ex-situ runout.

9. The method of claim 7, wherein the runout of the susceptor assembly that is determined and compared is in-situ runout.

10. The method of claim 7, further comprising:
receiving a plurality of radial displacement measurements from the first sensor, wherein the determining runout of the susceptor assembly is completed using the plurality of radial displacement measurements.

11. The method of claim 10, further comprising:
acquiring the plurality of radial displacement measurements via the first sensor, prior to the receiving the plurality of radial displacement measurements, wherein the first sensor is a non-contact sensor.

12. The method of claim 7, further comprising:
determining wobble of the susceptor assembly using a second sensor, wherein the second sensor is fixed relative to the turntable and axially offset from the first sensor; and
comparing the wobble to a predetermined wobble value and reworking the susceptor assembly in response to the wobble exceeding the predetermined wobble value,
wherein the disassembling the susceptor assembly additionally occurs in response to the wobble being below the predetermined wobble value.

13. The method of claim 12, further comprising:
receiving a plurality of axial displacement measurements from the second sensor, wherein the determining wobble of the susceptor assembly is completed using the plurality of axial displacement measurements.

14. A method, comprising:
slidably seating a susceptor assembly in a turntable for rotation about a rotation axis;
determining wobble of the susceptor assembly using a second sensor, wherein the second sensor is fixed relative to the turntable;
comparing the wobble to a predetermined wobble value and reworking the susceptor assembly in response to the wobble exceeding the predetermined wobble value; and
disassembling the susceptor assembly in response to the wobble being below the predetermined wobble value.

15. The method of claim 14, wherein the wobble of the susceptor assembly that is determined and compared is ex-situ wobble.

16. The method of claim 14, wherein the wobble of the susceptor assembly that is determined and compared is in-situ wobble.

17. The method of claim 14, further comprising:
receiving a plurality of axial displacement measurements from the second sensor, wherein the determining ex-situ wobble of the susceptor assembly is completed using the plurality of axial displacement measurements.

18. The method of claim 17, further comprising:
acquiring the plurality of axial displacement measurements via the second sensor, prior to the receiving the plurality of axial displacement measurements, wherein the second sensor is a non-contact sensor.

19. The method of claim 14, further comprising:
determining runout of the susceptor assembly using a first sensor, wherein the first sensor is fixed relative to the turntable and radially offset from the rotation axis; and
comparing the runout to a predetermined runout value and reworking the susceptor assembly in response to the runout exceeding the predetermined runout value,
wherein the disassembling the susceptor assembly additionally occurs in response to the runout being below the predetermined runout value.

20. The method of claim 19, further comprising:
receiving a plurality of radial displacement measurements from the first sensor, wherein the determining runout of the susceptor assembly is completed using the plurality of radial displacement measurements.
